(19) United States
(12) Patent Application Publication
(10) Pub. No.: US 2025/0321909 A1
(43) Pub. Date: Oct. 16, 2025

(54) 3D STACKED I/O CHIPLET ON OPTICAL INTERPOSER FOR HIGH BANDWIDTH APPLICATIONS

(71) Applicant: Lightmatter, Inc., Boston, MA (US)

(72) Inventors: Kuang Liu, Queen Creek, AZ (US); Sandeep Sane, Chandler, AZ (US); Bradford Turcott, Georgetown, TX (US); Taylor Groves, Poulsbo, WA (US); Robert Turner, Georgetown, TX (US); Nicholas C. Harris, Menlo Park, CA (US); Sriram Venkatesan, Fremont, CA (US); Mitul Modi, Phoenix, AZ (US); Krishna Bharath, Portland, OR (US); Rishi Anand, Nobleton (CA); Steven Klinger, Saratoga, CA (US); Darius Bunandar, Boston, MA (US)

(73) Assignee: Lightmatter, Inc., Boston, MA (US)

(21) Appl. No.: 19/179,721

(22) Filed: Apr. 15, 2025

Related U.S. Application Data
(60) Provisional application No. 63/634,892, filed on Apr. 16, 2024.
(60) Provisional application No. 63/750,028, filed on Jan. 27, 2025.
(60) Provisional application No. 63/779,749, filed on Mar. 28, 2025.

(51) Int. Cl. G06F 13/20; G06F 13/42

(52) U.S. Cl. CPC G06F 13/20; G06F 13/4221; G06F 13/4282; G06F 2213/0002; G06F 2213/0026

(57) ABSTRACT

Described herein is a novel approach that leverages a 3D stacked die complex with an active optical interposer integrated with an I/O chiplet including high-speed serializer/deserializer (SerDes). By integrating silicon in this way, shoreline constraints are eliminated, allowing for the SerDes macros to be placed virtually anywhere on the I/O chiplet. The photonic-based interconnects described herein improve upon conventional approaches based on co-packaged optics (CPO), Linear-drive Pluggable Optics (LPO) and copper-based solutions in terms of bandwidth and power consumption. The interconnects described herein rely on photonic-electronic packages in which a PIC provides processing units (e.g., XPU), electronic switching chips or other types of application-specific integrated circuits (ASIC) with access to optical fiber-based networks while multiple SerDes provide high-speed serialization and deserialization.

### CROSS-REFERENCE TO RELATED APPLICATIONS

This application claims the benefit under 35 U.S.C. § 119(e) of U.S. Provisional Patent Application Ser. No. 63/779,749, entitled “3D STACKED I/O CHIPLET ON OPTICAL INTERPOSER FOR HIGH BANDWIDTH SWITCHING APPLICATIONS,” filed on Mar. 28, 2025, under Attorney Docket No. L0858.70088US01; U.S. Provisional Patent Application Ser. No. 63/750,028, entitled “HIGH-SPEED PHOTONIC-ELECTRONIC INTERCONNECTS AND RELATED PACKAGES,” filed on Jan. 27, 2025, under Attorney Docket No. L0858.70116US00; and U.S. Provisional Patent Application Ser. No. 63/634,892, entitled “3D STACKED I/O CHIPLET ON OPTICAL INTERPOSER FOR HIGH BANDWIDTH SWITCHING APPLICATIONS,” filed on Apr. 16, 2024, under Attorney Docket No. L0858.70088US00, each of which is hereby incorporated herein by reference in its entirety.

### BACKGROUND

Optical transceivers are devices that transmit and receive data using light signals, typically over optical fiber cables. Optical transceivers play a crucial role in telecommunications and data communication networks, converting electrical signals into optical signals for transmission and then converting them back into electrical signals at the receiving end. Wavelength division multiplexing (WDM) is a technology used in optical communication to transmit multiple signals simultaneously over a single optical fiber. WDM achieves this by using different wavelengths (colors) of light for each signal, allowing for efficient use of the fiber's bandwidth and significantly increasing the data-carrying capacity.

### SUMMARY OF THE DISCLOSURE

Some embodiments relate to a photonic-electronic package, comprising a photonic integrated circuit (PIC) comprising a first plurality of through silicon vias (TSV) and a second plurality of TSVs; an electronic integrated circuit (EIC) mounted on the PIC, wherein the EIC comprises: an input-output (I/O) interface coupled to the first plurality of TSVs of the PIC; a plurality of serializer-deserializer (SerDes) coupled to the second plurality of TSVs of the PIC; and a data path coupling the I/O interface to at least one of the plurality of SerDes.

In some embodiments, the I/O interface is implemented in accordance with a Universal Chiplet Interconnect Express (UCIe) standard.

In some embodiments, the PIC further comprises a plurality of optical transmitters, wherein the second plurality of TSVs couple the plurality of optical transmitters to the plurality of SerDes.

In some embodiments, the PIC further comprises a waveguide and a fiber attach, wherein the waveguide couples the fiber attach to the plurality of optical transmitters.

In some embodiments, the photonic-electronic package further comprises a substrate and an electronic chip, wherein the PIC is mounted on the substrate and the electronic chip is mounted on the substrate.

In some embodiments, the substrate comprises a silicon bridge coupling the PIC to the electronic chip.

In some embodiments, the silicon bridge is implemented in accordance with an Embedded Multi-die Interconnect Bridge (EMIB) standard.

In some embodiments, the I/O interface of the EIC is implemented in accordance with a UCIe standard, and the electronic chip has an I/O interface that is implemented in accordance with the UCIe standard.

In some embodiments, the electronic chip comprises a plurality of nodes arranged in accordance with an N×M grid, wherein N>1 and M>1.

In some embodiments, a first node of the plurality of nodes is a 180°-rotated version of a second node of the plurality of nodes.

In some embodiments, the first plurality of TSVs have a first pitch and the second plurality of TSVs have a second pitch, wherein the second pitch is different from the first pitch.

In some embodiments, the second pitch is between 30 μm and 120 μm and the first pitch is between 30 μm and 90 μm.

In some embodiments, the EIC is hybrid-bonded to the PIC.

In some embodiments, the EIC is configured to perform link training, telemetry, statistics and/or performance optimization.

In some embodiments, the photonic-electronic package further comprises a plurality of trans-impedance amplifiers (TIA) coupled to the plurality of SerDes, wherein the plurality of TIAs are formed in the PIC or in the EIC.

Some embodiments relate to a method of operating a photonic-electronic package comprising a substrate, a photonic integrated circuit (PIC) mounted on the substrate, an electronic chip and an electronic integrated circuit (EIC) mounted on the PIC, the method comprising controlling an optical receiver formed on the PIC to generate electric signals by receiving optical signals though a fiber attach formed on the PIC; controlling a serializer/deserializer (SerDes) formed on the EIC to generate a serialized electrical signal upon receiving the electric signals from the optical receiver through a first set of through silicon vias (TSVs); controlling a first I/O interface, formed on the EIC, to transmit a message derived from the serialized electrical signal to a second I/O interface, formed on the electronic chip, through a second set of TSVs; and controlling the second I/O interface to provide the message to the electronic chip.

In some embodiments, the first and second I/O interfaces are implemented in accordance with a Universal Chiplet Interconnect Express (UCIe) standard.

In some embodiments, the method further comprises controlling one or more optical switches to route the optical signals from the fiber attach to the optical receiver.

In some embodiments, transmission of the message from the first I/O interface to the second I/O interface passes through a silicon bridge implemented in accordance with an Embedded Multi-die Interconnect Bridge (EMIB) standard.

In some embodiments, the method further comprises controlling the EIC to perform link training, telemetry, statistics and/or performance optimization on a data path coupling the SerDes to the first I/O interface.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a cross sectional view illustrating a photonic-electronic package, in accordance with some embodiments.

FIG. 1B is a block diagram illustrating components of the electronic integrated circuit (EIC) and photonic integrated circuit (PIC) of FIG. 1A, in accordance with some embodiments.

FIG. 1C is a flowchart illustrating a method for controlling a photonic-electronic package, in accordance with some embodiments.

FIG. 2 is a top view illustrating a photonic-electronic package, in accordance with some embodiments.

FIG. 3 is a top view illustrating another photonic-electronic package, in accordance with some embodiments.

FIG. 4A is a block diagram illustrating a system including optically interconnected processing units (XPU), in accordance with some embodiments.

FIG. 4B is a block diagram illustrating a system including optically interconnected switch chips, in accordance with some embodiments.

FIG. 4C is a block diagram illustrating a possible implementation of the system of FIG. 4A, in accordance with some embodiments.

FIG. 4D illustrates how a master XPU may be used to form a system with multiple XPUs, some of which being 180°-rotated, in accordance with some embodiments.

FIG. 4E is a block diagram illustrating another system including optically interconnected XPUs, in accordance with some embodiments.

FIG. 4F is a perspective view illustrating a chassis including the system of FIG. 4A, in accordance with some embodiments.

FIG. 5 is a cross sectional view illustrating a photonic-electronic package including an interposer, in accordance with some embodiments.

FIG. 6 is a cross sectional view illustrating another photonic-electronic package including an interposer, in accordance with some embodiments.

FIG. 7 is a cross sectional view illustrating a photonic-electronic package including a redistribution layer (RDL), in accordance with some embodiments.

FIG. 8 is a block diagram illustrating a possible implementation of the PIC of FIG. 1A using reticle stitching, in accordance with some embodiments.

### DETAILED DESCRIPTION

Today's high bandwidth processor and switches are migrating away from monolithic single reticle designs to multi-die systems including a collection of chiplets. The drive behind these architectural changes is to increase the available shoreline to improve serializer/deserializer (SerDes) density per package, resulting in increased bandwidth. The “shoreline,” also referred to as the “beachfront,” is a term used in semiconductor packaging to refer to the boundary or edge of a chip, package, or substrate where connections (e.g., bond pads, I/O terminals, solder balls) are made. Due to signal integrity constraints, it is only practical to place SerDes macros within a couple of millimeters from the edge, creating a significant shoreline limitation. These limitations are compounded by the relatively large area associated with today's Long Reach (LR) SerDes macros. As these trends continue, the size of high bandwidth chips is expected to continue to grow, resulting in increased complexity and manufacturing cost. Based on current LR SerDes macro sizes, a design targeting 409.6 Tbps of switch bandwidth in a single package will likely require more than four full reticle (e.g., 26 mm xx 33 mm) chiplets, driven primarily by the shoreline required to support the bandwidth targets. Lastly, these issues are amplified by the complexity in increasing SerDes data rates and the reduced drive distance that is achievable as SerDes speeds increase, resulting in more complex board/system designs and external optical transceivers to support inter-rack communication.

The inventors have recognized the need to address the shoreline limitations while simultaneously bringing optics closer to the physical layer (PHY) of the SerDes macros. Described herein is a novel approach that leverages a 3D stacked die complex with an active optical interposer integrated with an I/O chiplet including high-speed SerDes. By integrating silicon in this way, the shoreline constraints are eliminated, allowing for the SerDes macros to be placed virtually anywhere on the I/O chiplet. Furthermore, due to the physical locality of the SerDes PHY to the relevant components in the optical interposer, area optimized Extra Short Reach (XSR) SerDes can be used, resulting in increased bandwidth density per mm² relative to LR SerDes. Optical interposers of the types described herein are also referred to as photonic integrated circuits (PIC). I/O chiplets of the types described herein are also referred to as electronic integrated circuits (EIC).

The inventors have developed photonic-based interconnects that improve upon conventional approaches based on co-packaged optics (CPO), Linear-drive Pluggable Optics (LPO) and copper-based solutions in terms of bandwidth, radix, reach and power consumption. The interconnects developed by the inventors and described herein rely on photonic-electronic packages in which a PIC provides electronic chips such as processing units (e.g., XPU), switch chips or other types of application-specific integrated circuits (ASIC), with access to optical fiber-based networks while multiple SerDes provide high-speed serialization and deserialization. Interconnects of the types described herein may support several communication protocols, including Ethernet, Peripheral Component Interconnect Express (PCIe), Universal Chiplet Interconnect Express (UCIe), Bunch of Wires (BoW), NVLINK, etc. A UCIe interface may include a UCIe-AP interface or a UCle-SP interface.

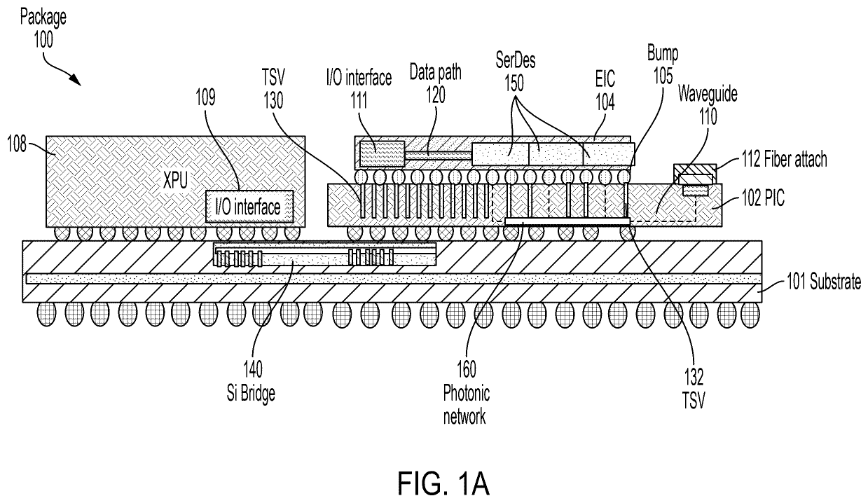

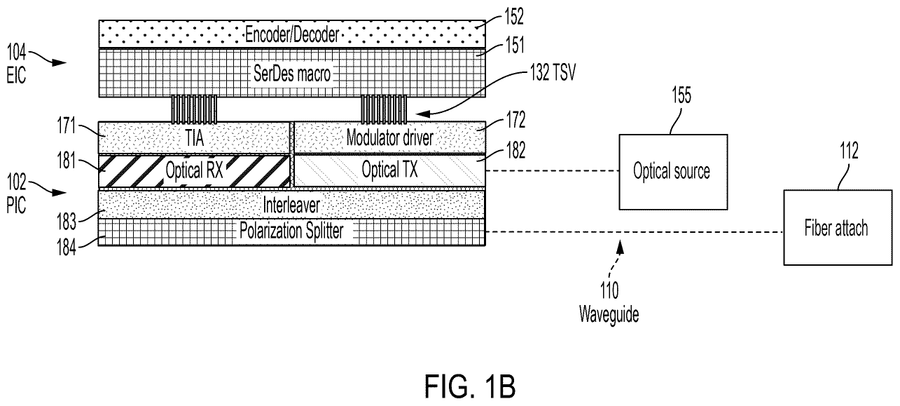

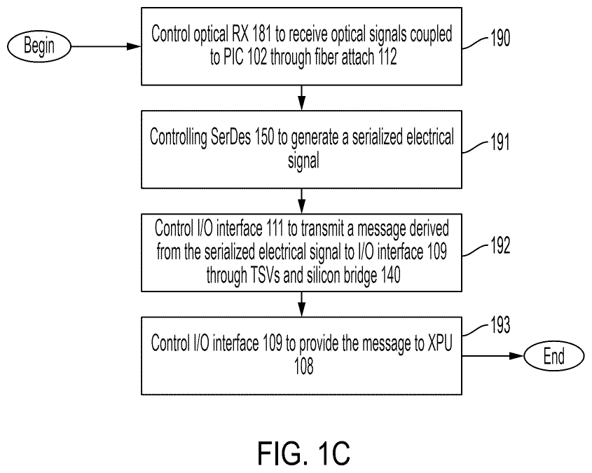

FIG. 1A is a cross sectional view illustrating a photonic-electronic package in accordance with some embodiments. Package 100 includes a substrate 101, on which a photonic integrated circuit (PIC) 102 and a processing unit (XPU) 108 are mounted side-by-side. An electronic integrated circuit (EIC) 104 is mounted on the PIC. EIC 104 serves as an I/O chiplet, placing XPU 108 in optical communication with devices outside substrate 101. To provide serialization and deserialization, EIC 104 is equipped with multiple SerDes 150. It should be noted that while FIG. 1A illustrates an arrangement in which the EIC is mounted on the PIC, the opposite arrangement is also possible such that the PIC may be mounted on the EIC. The EIC and the PIC of FIG. 1A are connected to one another via bumps 105. However, other types of connections are also possible, including through hybrid bonding. Hybrid bonding enables direct metal-to-metal (e.g., copper-to-copper) and dielectric-to-dielectric bonding between chips, without the need for traditional bumps (such as micro-bumps used in flip-chip technology). By removing bumps and using hybrid bonding, the distance between the electrical connections connecting the PIC and the EIC can be reduced, allowing a greater number of connections.

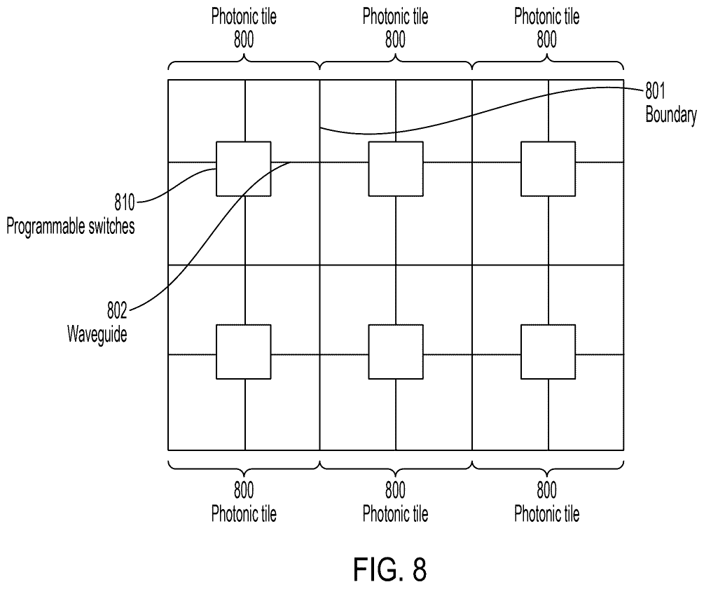

PIC 102 may be fabricated using silicon photonics fabrication techniques. In some embodiments, PIC 102 is fabricated using reticle-stitching, a lithographic technique to fabricate larger-than-reticle photonic networks by combining multiple exposure fields (“reticles” or “tiles”) into one continuous optical structure. However, not all embodiments are limited in this respect. An example of a reticle-stitched PIC is described below in connection with FIG. 8.

XPU 108 may be implemented to operate as a data processing unit (DPU), an infrastructure processing unit (IPU), a function accelerator card (FAC), a network attached processing unit (NAPU), a compute processing unit (CPU), a graphic processing unit (GPU), a field programmable gate array (FPGA), an application specific integrated circuit (ASIC), or a neuromorphic computing, for example.

XPU 108 includes an input/output (I/O) interface 109 that allows the XPU to communicate with the other components within the package. I/O interface 109 may be implemented in accordance with a Universal Chiplet Interconnect Express (UCIe) standard (including for example UCIe-AP or UCIe-SP), an open industry standard designed to enable seamless communication between chips within a single package. Alternatively, I/O interface 109 may be implemented in accordance with other standards, including for example die-to-die Advanced Interface Bus (AIB), Ethernet, Peripheral Component Interconnect Express (PCIe), Bunch of Wires (BoW), NVLINK, etc.

Substrate 101 can include a silicon bridge 140, a piece of silicon embedded in the substrate acting as a physical and electrical interconnect between PIC 102 and XPU 108. Unlike full-sized interposers, silicon bridge 140 is smaller and occupies only the region of the substrate directly underneath the interfaces of the chips. The silicon bridge may be implemented in accordance with an Embedded Multi-die Interconnect Bridge (EMIB) standard (e.g., EMIB-T) or CoWoS-L, among other protocols. A corresponding I/O interface 111 is formed on EIC 104. To permit communication between I/O interface 109 and I/O interface 111, these I/O interfaces may be implemented in accordance with the same protocol. Alternatively, in lieu of silicon bridge 140 on substrate 101, PIC-XPU connections may be routed on a wafer through Chip-on-Wafer-on-Substrate (CoWoS).

PIC 102 is mounted on the substrate near XPU 108. The position of PIC 102 relative to XPU 108 is sufficiently small so as to allow silicon bridge 140 to exchange data between them. For example, both PIC 102 and XPU 108 may be disposed directly on top of silicon bridge 140.

PIC 102 includes a photonic network 160 including waveguides, optical transceivers (transmitters and receivers), programmable photonic switches and couplers. An example implementation of photonic network 160 is described below in connection with FIG. 1B. The programmable optical switches can be controlled to route optical signals within PIC 102 where desired. In addition, the programmable optical switches can also be used to route one or more optical signals from a light source (e.g., a laser) to the transmitters within PIC 102 where needed. The optical transceivers provide optical-electrical conversion and electrical-optical conversion, allowing EIC 104 to transmit signals through the fibers and receive signals from the fibers. The optical transceivers may support different data rates, including for example 56G non-return to zero (NRZ), 106G pulse-amplitude modulation (e.g., PAM4), etc. NRZ may be performed on the basis of two levels, with one bit per transmission. PAM4 may be performed on the basis of four levels, with two bits per transmission. Optical fibers can be attached to and optically coupled the fiber attaches 112, thereby coupling PIC 102 to an external device and/or external optical networks. A fiber attach 112 may include edge couplers or out-of-plane couplers. Trans-impedance amplifiers (TIA) and modulator drivers may be used to allow the SerDes to electrically interface with the transceivers. The TIAs and modulator drivers may be formed in the EIC or in the PIC. In some embodiments, placing the TIAs and drivers in the EIC allows fabrication using smaller fabrication nodes than what would otherwise be practical if they were placed in the PIC. This reduces the dimension of these components and their power consumption. The drawback is that additional EIC-PIC connections (e.g., bumps) would be needed to interface the TIAs and modulator drivers with the transceivers. However, use of hybrid-bonded EIC-PIC connections can alleviate this issue because metal-to-metal connections can be made with a significantly smaller pitch than bumps.

PIC 102 includes through silicon vias (TSV), which permit electrical-domain communication across the PIC in the vertical direction. In this example, PIC 102 is mounted with the top side facing the substrate and the back side facing the EIC, but the opposite arrangement is possible. A first set of TSVs 130 couple I/O interface 111 to substrate 101. A second set of TSVs 132 are coupled to the SerDes 150. The SerDes 150 drive the transceivers of the PIC through the second set of TSVs 132, enabling signal serialization and deserialization. Data path 120, defined within EIC 104, connects I/O interface 111 to the SerDes 150. Shims, glue or other fasteners may be used to ensure proper connection between I/O interface 111 and the SerDes 150.

In some embodiments, the TSVs of the set that couple to I/O interface 111 (TSVs 130) may have a different density relative to the TSVs of the set that couple to the SerDes 150 (TSVs 132). Thus, the TSVs 130 may be spaced from one another with a pitch that is different from (e.g., smaller than) the pitch of the TSVs 132. The TSVs 130 may be spaced from one another with a pitch that is between 30 μm and 120 μm, between 30 μm and 90 μm, between 30 μm and 60 μm, between 30 μm and 50 μm, between 40 μm and 50 μm, between 50 μm and 120 μm, between 70 μm and 120 μm, between 90 μm and 120 μm, between 100 μm and 120 μm, or between 110 μm and 120 μm. The TSVs 132 may be spaced from one another with a pitch that is between 30 μm and 120 μm, between 30 μm and 90 μm, between 30 μm and 60 μm, between 30 μm and 50 μm, between 40 μm and 50 μm, between 50 μm and 120 μm, between 70 μm and 120 μm, between 90 μm and 120 μm, between 100 μm and 120 μm, or between 110 μm and 120 μm. The pitches of the sets of TSVs may be chosen to reflect the density of the connections in the underlying components. For example, the density of the connections of silicon bridge 140 tends to be significantly greater than the density of the photonic transceivers in PIC 102.

Additionally or alternatively, the pitch of the TSVs 130 may be chosen to reflect the type of I/O interface 111 used. For UCIe AP interfaces, for example, the pitch may be between 40 μm and 50 μm. For UCle SP interfaces, the pitch may be between 100 μm and 120 μm. In some embodiments, the pitch of the TSVs 130 is between 30 μm and 50 μm and the pitch of the TSVs 132 is between 40 μm and 50 μm. In other embodiments, the TSVs 132 may be spaced from one another with a pitch that is smaller than the pitch of the TSVs 130.

When the PIC and the EIC are hybrid bonded to each other, the pitch of the TSVs 132 and the bumps may be reduced to 10 μm or less.

FIG. 1B is a block diagram illustrating some of the components of EIC 104 and PIC 102, in accordance with some embodiments. As described above, EIC 104 includes multiple SerDes 150, represented in FIG. 1B collectively as SerDes macro 151. An encoder/decoder 152 encodes data to, and decodes data from, SerDes macro 151. Encoder/decoder 152 may further perform continuous-time linear equalization (CTLE), in some embodiments. The SerDes are coupled to TIAs 171 and modulator drivers 172 through TSVs 132. Modulator drivers 172 translate the signals provided by the SerDes to a level suitable for driving the optical transmitter (TX) 182. Optical TX 182 may include a bank of optical modulators configured to encode data in the optical domain using wavelength division multiplexing (WDM). An optical source 155 (not shown in FIG. 1A) provides light to TX 182 in the form of multiple spectral peaks suitable for use in WDM. TIAs 171 translate the signals produced by the optical receiver (RX) 181 to a level suitable for the SerDes. Optical RX 181 may include ring drop filters coupled to a bus and photodetectors coupled to respective ring drop filters.

An interleaver 183 is configured to allow TX 182 and RX 181 to communicate with other devices bidirectionally while avoiding interference between signals traveling in opposite directions. Interleaver 183 may be designed to promote selective coupling using a combination of constructive and destructive interference. Wavelengths that are coupled from TX 182 to an off-chip optical channel thanks to constructive interference do not couple to RX 181 because of destructive interference. Similarly, wavelengths that are coupled from the off-chip optical channel to RX 181 thanks to constructive interference do not couple to TX 182 because of destructive interference. In some embodiments, selective coupling is achieved using interferometers designed to provide spectral responses that are x-shifted relative to one another. For example, at one terminal, the interferometer may exhibit a certain spectral response and, at another terminal, the interferometer may exhibit a x-shifted version of the same spectral response. Some embodiments employ asymmetric Mach Zehnder interferometers (MZI) to produce this effect. Polarization splitter 184 separates light received from the fibers into a TE component and a TM component. In some embodiments, the TM component may be rotated to produce a further TE component. Waveguide 110 couples the optical components of PIC 102 to fiber attach 112, to which optical fibers are connected.

In some embodiments, PIC 102 sends and receives signals from another PIC bidirectionally in one or more optical fibers. The bidirectional signals can be encoded in one or more different optical modes within the fiber. For example, signals being sent by PIC 102 can be encoded in the horizontal polarization and signals being received by PIC 102 are encoded in the vertical polarization (sometimes referred to as TE and TM modes). In another case, the signals being sent by PIC 102 are encoded in one or more wavelengths of light and the signals being received by PIC 102 are encoded in a different set of wavelengths of light. Any combination of wavelength modes and polarization modes can be used as a different encoding.

In some embodiments, the signals sent and received by PIC 102 are transmitted through two or more independent optical fibers. The optical fibers can be multi-mode fibers, multi-core fibers, single-mode fibers, and polarization-maintaining fibers. Since the signals are transmitted through different optical fibers, the signals being sent and received can be encoded in the same polarization or wavelength mode (but different spatial mode).

In terms of receiving the data, the optical receivers 181 can use polarization diversity architecture where the two components of light (TE and TM) from polarization splitter 184 are sent to a dual-ended photodetector that generates a single output photocurrent. In another embodiment, the two components of the light signals are sent to two independent balanced photodetectors whose output photocurrent are summed in Kirchoff's law fashion. In either case, both components of light signals should be path-length matched down to a fraction of the “unit interval” or UI, as the SerDes 151's clock and data recovery can only tolerate some skew.

In another embodiment, the two components of light (TE and TM) can be combined coherently using an interferometer (such as an MZI) placed right after the polarization splitter 184. In some embodiments, polarization diversity architecture isn't necessary when the signals are received via polarization-maintaining fibers when the signals have a definite maintained polarization despite any thermal stress on or physical movements of the fibers.

PIC 102 may include a microcontroller for initializing and stabilizing all the optical components. Additionally, PIC 102 may have an additional UCle or other die-to-die interface to communicate with the other chiplets or with the EIC 104 electrically. In another embodiment, the microcontroller can be an external microcontroller die, placed in the same package or on the substrate. This external microcontroller die can communicate to the PIC or the EIC via UCIe interface or other standard digital interfaces such as JTAG or QSPI.

The optical source 155 can be co-integrated with the PIC 102 or it can be delivered via optical fibers from an external light source module. The light source can be a laser, an LED, or a μLED. The optical fibers from the external light source module can be polarization maintaining, which can be maintained to be cost efficient if the distance between the optical source 155 and the PIC 102 is short. When the optical source 155 is co-integrated with the PIC, the light is coupled to directly one or more waveguides and are delivered to the transmitters via those waveguides.

In some embodiments, optical transceivers in PIC 102 are associated with one another in pairs statically in accordance with a wavelength division multiplexing (WDM) scheme. For example, WDM links may be defined so that each optical transmitter is uniquely associated with a respective optical receiver. The optical transmitters may include ring modulators and the optical receivers may include ring drop filters coupled to a bus and photodetectors coupled to respective ring drop filters. Each transmitter is associated with a particular receiver on the basis of exhibiting the same resonant wavelength. Heaters may be used to ensure that the ring modulators and the ring drop filters are properly tuned to the desired WDM channel. However, manufacturing imperfections may make this scheme energy inefficient. For example, a scenario may emerge in which tuning a particular ring modulator to the desired WDM channel may be more costly (from an energy perspective) than tuning a different modulator to that WDM channel. Unfortunately, this scheme does not provide much flexibility in terms of which transmitter and receiver is associated with which WDM channel. The inventors propose an alternative scheme that allows any WDM channel to be associated with any transmitter and any receiver in a controllable fashion. In some embodiments, this is accomplished using crossbars. This scheme results in lower energy consumption because the amount of energy that needs to be expended to tune the resonators can be reduced significantly. The crossbar may be disposed in EIC 104, electrically between the SerDes 150 and the TIAs/modulator drivers. With the crossbars, SerDes 150 may be assigned to transceivers dynamically (as opposed to having to assign SerDes to transceivers in a static, permanent fashion).

Additionally, or alternatively, crossbars may be used to allow dynamic associations between SerDes 150 and I/O interfaces 111 (as opposed to having to assign SerDes to I/O interfaces in a static, permanent fashion). In turn, this scheme allows I/O interfaces 111 to be associated to fibers arbitrarily.

A cross-bar may be available in the SerDes macro 151 so that any SerDes lane can be associated with any ring modulator. A different additional cross-bar may be available to assign which UCle macro to be associated with which SerDes macro 151. Additionally, EIC 104 may contain a medium access control (MAC) sublayer or the physical coding (PCS) sublayer. Either of these sublayer can also be contained within the PIC 102.

The SerDes 150 may be one operating with clock and data recovery (CDR) or may be one operating with clock-forwarding. In clock-forwarding, the clock is also received by the SerDes receiver either from light of another wavelength or another polarization traveling in the same optical fiber as the signals, or the slower clock can be encoded in some slow modulation of all the signals. For example, slower clocks may be at 1/16, ⅛, ¼, or ½ of the line transmission rate. In the clock-forwarded scheme, the clock has reduced common jitter as both the signals and the clock have traveled through the same physical components. The clock can be generated at the receiving SerDes in the CDR scheme or the clock-forwarded scheme.

In some embodiments, a controller formed on EIC 104 may operate in conjunction with the PIC to perform link training, telemetry, statistics and performance optimization on a data path.

Some embodiments relate to a method of operating package 100 to permit communication to and from an electronic chip (e.g., XPU 108 or other types of chips, including switch chips, examples of which are described in detail further below). The steps of the method of FIG. 1C may be performed using one common controller or multiple controllers. The controller(s) may be positioned outside package 100 and/or inside package 100. When inside package 100, the controller(s) may be part of circuitry defined in PIC 102, EIC 104 and/or XPU 108 (or switch chip 460.).

The method begins at step 190, which involves controlling optical RX 181 to receive optical signals through fiber attach 112. Optionally, prior to being received by optical RX 181, the optical signals may be routed to the desired photodetectors using one or more programmable optical switches, examples of which are described in detail further below. Upon reception, optical RX 181 transforms the optical signals into electrical signals. Controlling optical RX 181 may involve tuning the ring drop filters to the desired WDM channel and/or biasing the photodetectors so that, when an optical signal is received, a photocurrent corresponding to the optical signal can be generated.

Step 191 involves controlling SerDes 150 to generate a serialized electrical signal. This involves serializing the electrical signals generated by optical RX 181 at step 190. The SerDes 150 receive the electrical signals from optical RX 181 through TSVs 132.

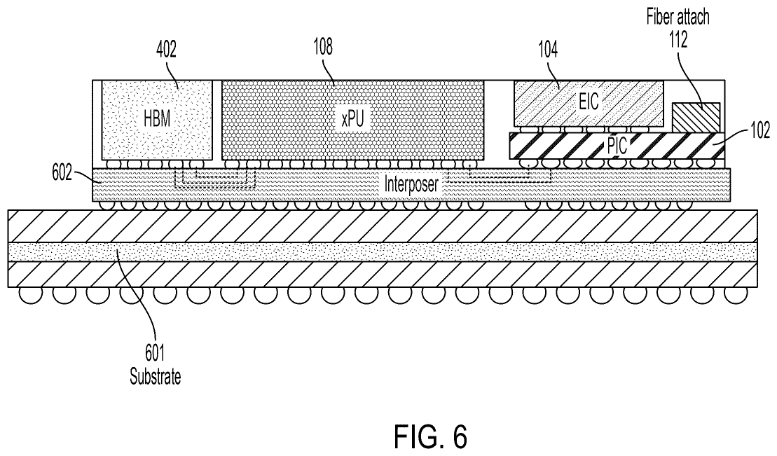

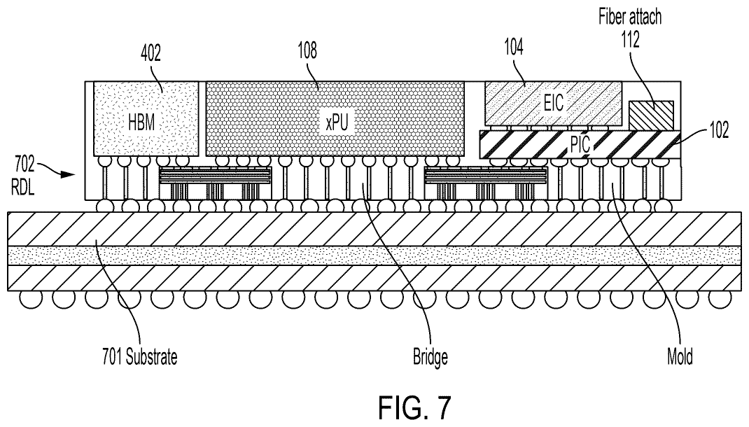

Step 192 involves controlling I/O interface 111 to transmit a message derived from the serialized electrical signal to I/O interface 109 through TSVs 130 and silicon bridge 140. In some embodiments, other platforms may be used instead of a silicon bridge including for example an interposer 602 (FIG. 6) and a redistribution layer 702 (FIG. 7). Interposer 602 may be made of silicon, organic materials or glass. I/O interface 111 receives the serialized electrical signal from SerDes 150 through a data path 120. The message may include the serialized electrical signal without any changes to it, or may include signals obtained by processing the serialized electrical signal in some way. For example, I/O interface 111 may attach a header to the payload extracted from the serialized signal. The header may indicate the destination of the message (e.g., a particular XPU 108) and/or other routing information.

Step 193 involves controlling I/O interface 109 to provide the message to XPU 108 (or other types of chips included in the package).

A similar method (not illustrated in FIG. 1C) may be executed to transmit information in the opposite direction, from XPU 108 to a device outside package 100. The method involves 1) controlling I/O interface 109 to transmit a message to I/O interface 111 through silicon bridge 140 (or other means such as interposer 602 or RDL 702) and TSVs 130, 2) controlling I/O interface 111 to transmit an electrical signal derived from the message to SerDes 150 via a data path 120, 3) controlling SerDes 150 to generate a deserialized electrical signal by deserializing the electrical signal, and 4) controlling optical TX 182 to modulate the deserialized electrical signal for transmission outside package 100 via fiber attach 112.

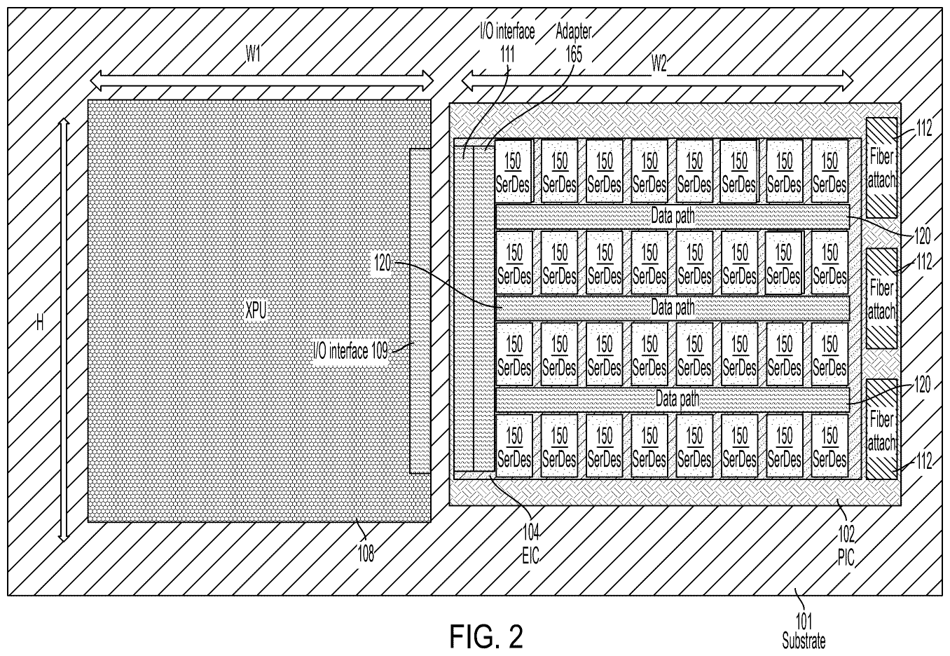

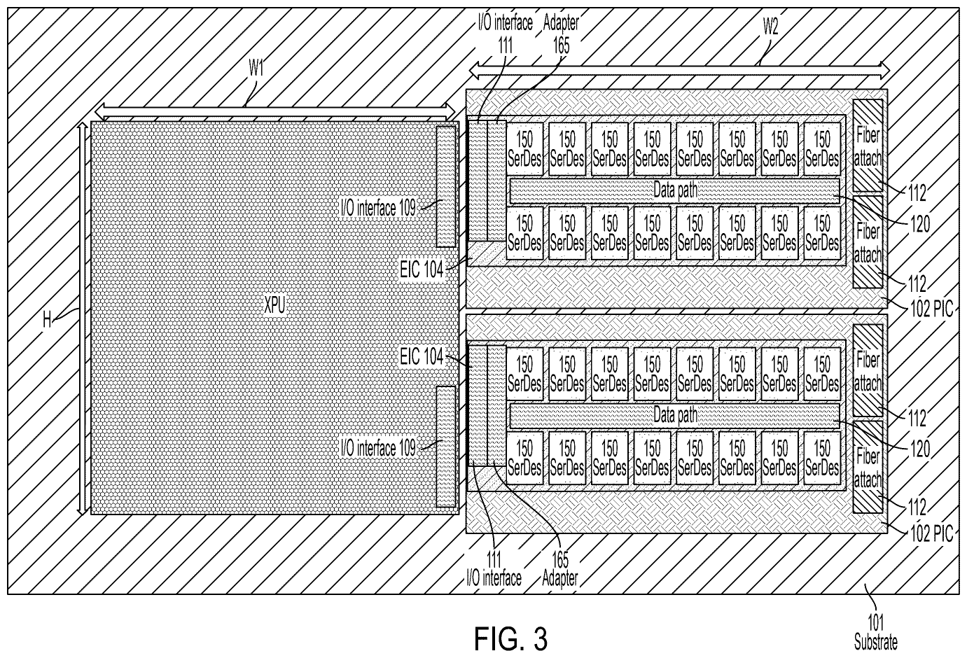

FIGS. 2-3 are top views illustrating two potential implementations of the package of FIG. 1A. These implementations facilitate optical access to multiple XPUs, although the packages of the types described herein may be used to facilitate access to different types of electronic chips, including for example switch chips, examples of which are described below.

The implementation of FIG. 2 includes, for each XPU 108, one PIC 102 and one EIC 104 mounted on PIC 102. By contrast, the implementation of FIG. 3 includes, for each XPU 108, two PICs 102 and two EICs 104, each EIC 104 being mounted on a respective PIC 102. Each EIC 104 communicates with a respective I/O interface 109 (on XPU 108) through an I/O interface 111. In yet other implementations, more than two PICs and EICs per XPU may be used. As shown in FIGS. 2-3, an EIC 104 includes multiple sets of SerDes 150 connected to I/O interface 111 through data paths 120. Use of SerDes to serialize and deserialize signals improves the bandwidth of the package significantly. In some embodiments, an EIC 104 can further include adapter 165, a component that facilitates communication and interoperability between multiple dies. For example, adapter 165 may include a Die-to-Die (D2D) adapter in the path between I/O interface 111 and SerDes 150.

The XPUs of FIGS. 2-3 may be implemented using a single compute node. In these examples, the XPU die may have a height H that is between 20 mm and 40 mm, between 25 mm and 35 mm, or between 30 mm and 34 mm. The XPU die may have a height W1 that is between 15 mm and 35 mm, between 20 mm and 30 mm, or between 24 mm and 28 mm. The width W2 of PIC 102 may be between 15 mm and 35 mm, between 20 mm and 30 mm, or between 23 mm and 27 mm. In some embodiments, the size of the XPU die may correspond to the size of the reticle shot available at a semiconductor foundry (e.g., 32 mm×26 mm). However, multi-reticle XPUs can be used in some embodiments.

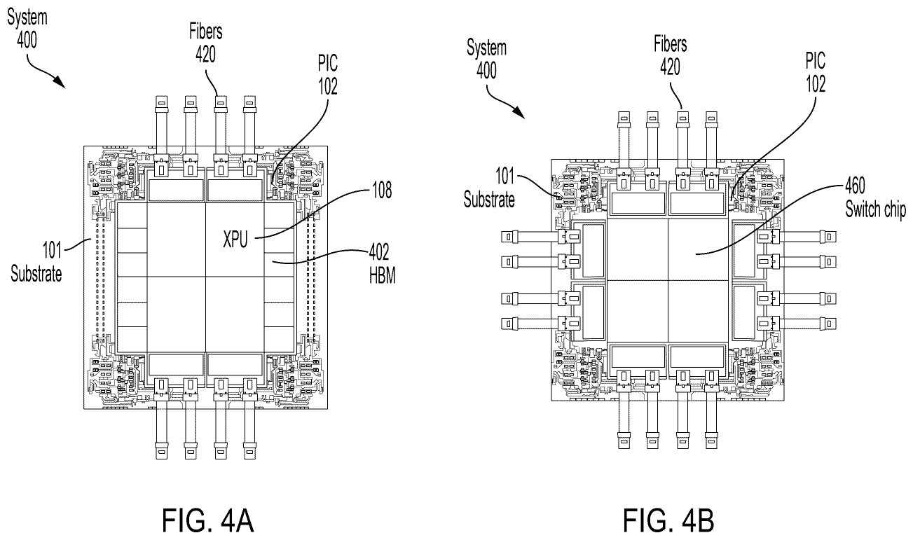

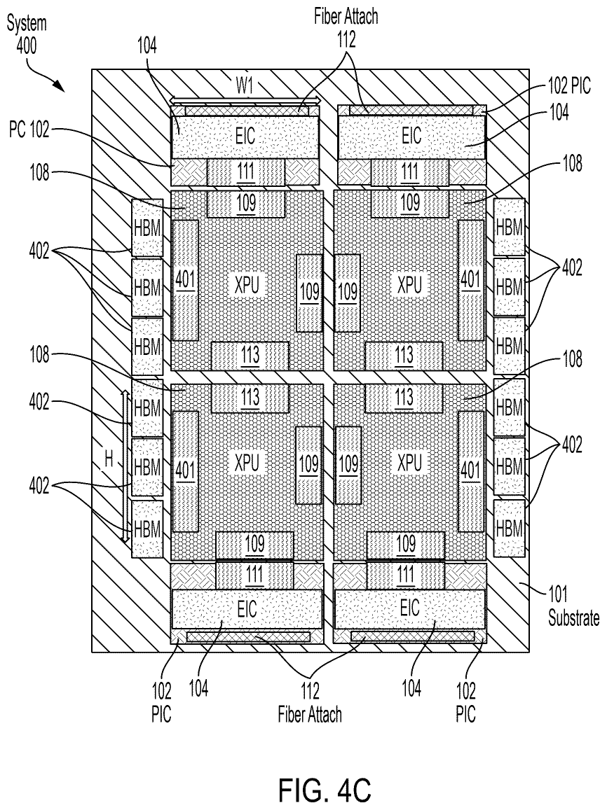

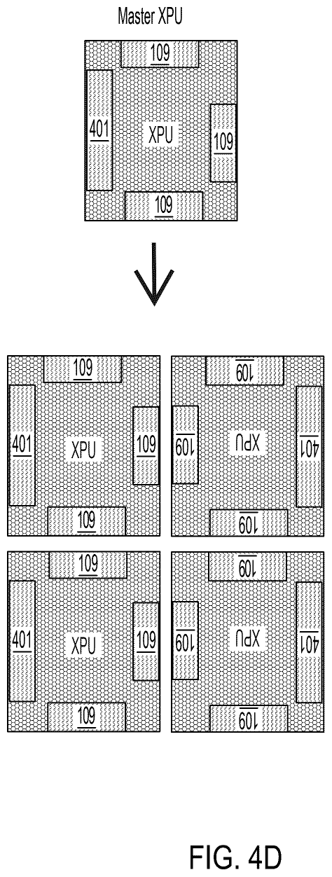

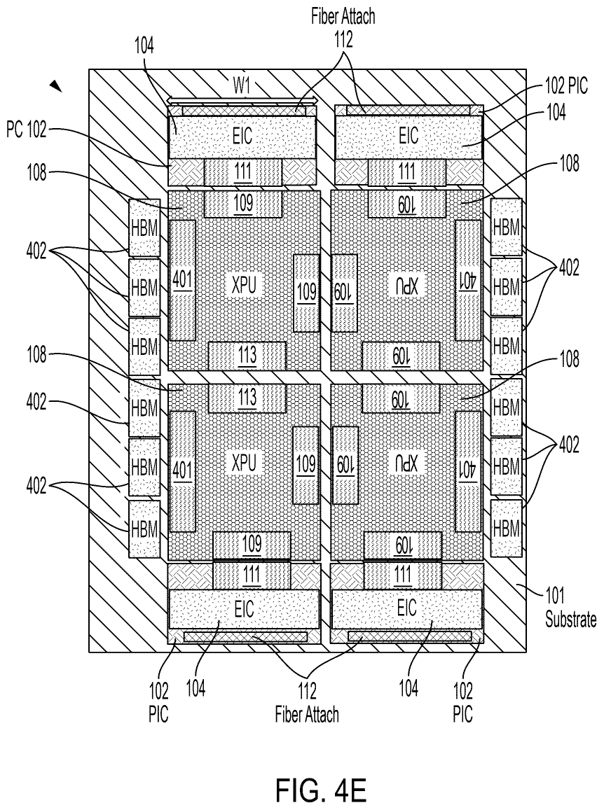

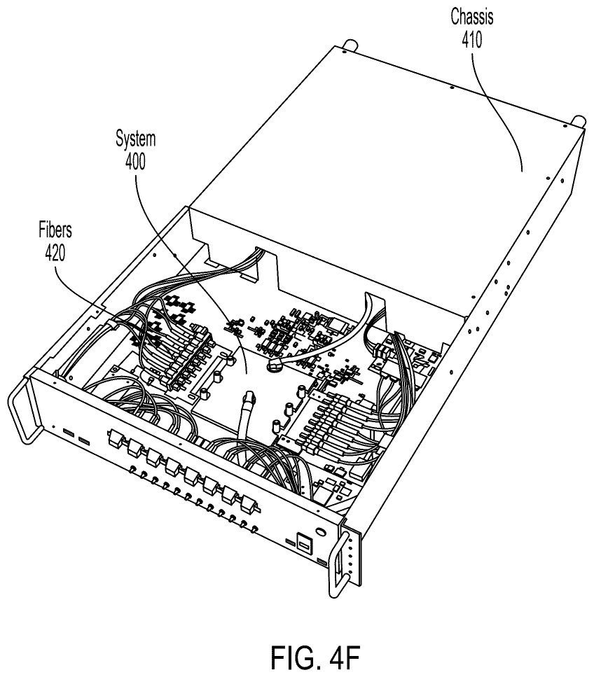

As discussed above, a package 100 may be used to facilitate optical communication to and from XPUs or other types of electronic chips, including switch chips. FIGS. 4A-4B are top views of two systems implemented using package 100, in accordance with some embodiments. System 400 (FIG. 4A) includes multiple XPUs 108, while system 450 (FIG. 4B) includes multiple switch chips 460. A switch chip 460 is a specialized microchip that performs the core functions of a network switch, including for example routing data packets between devices on a network, such as computers, servers, and routers. Both systems 400 and 450 are packaged with PICs 102 and EICs 104 in the manner discussed in connection with FIG. 1A. System 400 includes, in addition to the XPUs, a set of high-bandwidth memory chips (HBM) 402 associated with each XPU. Each XPU 108 is associated with three HBMs in this example (although any other suitable number of HBMs per XPU is possible), and an EIC/PIC pair (although as noted above more than one EIC/PIC per XPU is possible). Each XPU may communicate with the HBMs with a UCle interface (e.g., UCIe-AP or UCIe-SP) or any due-to-die interface compatible with the HBMs and the memory controller with the XPU. The system of FIG. 4A includes a grid of 2×2 XPUs. More generally, a system 400 can include a grid of N×M compute nodes, wherein N>1 and M>1. The XPUs of the grid may be instantiations of a reticle shot. In some embodiments, the reticle is rotated (e.g., by 180 degrees) between a reticle instantiation and another. Therefore, adjacent XPUs may be patterned so that one XPU is a rotated version of another XPU. The XPUs communicate with the HBM in the east-west direction, and with the EICs in the north-south direction.

The system of FIG. 4B includes a grid of 2×2 switch chips 460. More generally, a system 450 can include a grid of N×M switch chips, wherein N>1 and M>1. The switch chips communicate with the EICs both in the west-east direction and in the north-south direction. As for XPUs 108, in some embodiments, a pair of adjacent switch chips may be 180°-rotated versions of one another. For example, the layouts of the chips may be identical to one another, but one node of the pair is rotated by 180° relative to the other node of the pair. Designing the package to permit use of switch chips that are 180°-rotated versions of one another allows system architects to source a single type of chip, which reduces costs.

FIG. 4C illustrates a potential implementation of system 400, in accordance with some embodiments. A similar architecture may be used to implement system 450. As discussed above, each XPU includes an I/O interface 109 communicating with a corresponding I/O interface 111 on an EIC 104. I/O interfaces 113 enable direct communication between the XPUs. I/O interfaces 401 enable direct communication between an XPU and the HBMs 402. I/O interfaces 109, 113 and 401 may be implemented based on the same protocol (e.g., UCIe) or different protocols.

As described above, in some embodiments, the XPUs of a package may be implemented using the same master XPU, but some of them may be rotated relative to one another to permit connections from different directions in the package. For example, FIG. 4D illustrates how a master XPU may be used to form a system with multiple XPUs, some of which being 180°-rotated. In this example, the master XPU includes three I/O interfaces 109 positioned on three sides of the XPU (north, east and south), and an I/O interface 401 positioned on the fourth side (west). Each I/O interface 109 can support connection either to another XPU or to a PIC/EIC. An I/O interface 109 may use the same communication protocol, whether it communicates with another XPU or a PIC/EIC. I/O interface 401 supports connection with HBMs. A system can be implemented using four instances of the master XPU, as further shown in FIG. 4E. The XPUs positioned on the upper left corner and lower left corner resemble the orientation of the master XPU. The XPUs positioned on the upper right corner and lower right corner are rotated by 180° relative to the master XPU. I/O interfaces 109 that face one another (those positioned on the west/east sides of the XPUs) support XPU/XPU communication. I/O interfaces 109 that face away from the package (those positioned on the north/south sides of the XPUs) support communication with PICs/EICs (as shown for example in FIGS. 1A or 5-7). A similar approach may be used for the switch chips of FIG. 4B. It should also be noted that not all the chips of the system of FIG. 4E need to be XPUs. For example, some of the XPUs may be replaced by switch chips in some embodiments.

FIG. 4F is a perspective view illustrating a chassis including the system of FIG. 4A, in accordance with some embodiments. As shown, a system 400 is embedded inside a chassis 410, with fibers 420 connecting to fiber attaches 112. Fiber attaches 112 may be directly bonded (either via laser melting or via glue or epoxy) to the corresponding attach points in the PIC. In another embodiment, a glass package or an organic package may be bonded to fiber attach points in the PIC to make the fibers detachable. A server rack may include multiple instances of chassis 410 stacked on top of each other and interconnected with one another.

Although the system of FIGS. 4A includes XPUs and HBMs and the system of FIG. 4B includes switch chips, other systems may use multiple types of chips in the same package. For example, a system may include any suitable combination of XPUs (including different types of XPUs, such as CPUs, GPUs, etc.), HBMs, switch chips, I/O chips, etc. Each chip may connect to a PIC n in the manner described herein.

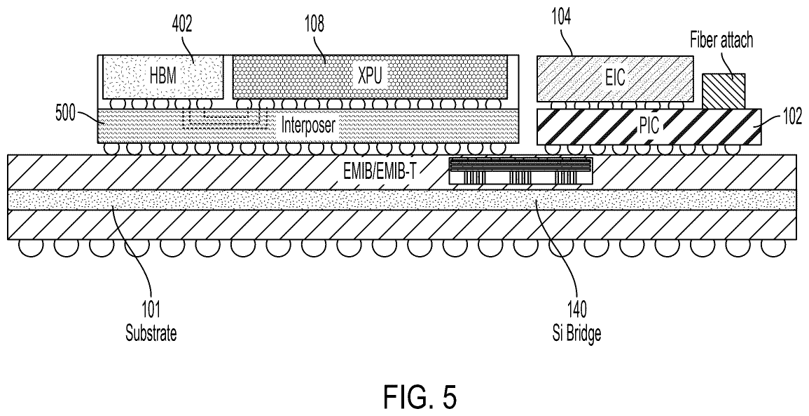

FIG. 5-7 are cross-sectional views of alternative packages that may be used in connection with the systems described herein. These packages are similar to the package of FIG. 1A, with some differences. In the package of FIG. 5, XPU 108 and HBMs 402 are mounted on a common interposer 500, instead of being mounted directly on substrate 101. In this implementation, XPU 108 and HBMs 402 communicate with each other through electrical channels defined in interposer 500. The package of FIG. 6 is similar to the package of FIG. 5 in that it also includes an interposer 600. In this implementation, however, PIC 102 also communicates with XPU 108 through interposer 602. Interposer 602 is mounted on substrate 601. Lastly, in the package of FIG. 7, XPU 108 communicates with PIC 102 and HBM 402 through silicon bridges formed in a redistribution layer (RDL) 702, mounted on substrate 701.

In some embodiments, the PIC may be fabricated by stitching multiple reticles (also referred to herein as “tiles” or “photonic modules”) to one another. Each tile may represent the instantiation of a reticle shot. Most photolithography systems (e.g., ASML steppers) have a maximum reticle field size (e.g., 26 mm×33 mm for deep ultra violet lithography). However, it may be desirable to design a PIC 102 to exceed this size to increase the aggregate bandwidth beyond what is practical with one reticle. To overcome this limitation, reticle stitching may be used to tile together multiple exposure fields on the wafer, similar to puzzle pieces. These sections are separately exposed on the wafer using precise stage movement and alignment. The stitch boundaries (the borders between exposures) should be tightly aligned, often within nanometer tolerances, to ensure optical continuity between waveguides of adjacent tiles.

FIG. 8 is a block diagram illustrating a possible implementation of the photonic network 160 of a PIC 102, in accordance with some embodiments. In this example, the photonic network is patterned using reticle stitching techniques to define six photonic tiles 800, arranged in a 3×2 grid. Being instantiations of a common photomask set, the tiles may be patterned identically to one another in some embodiments. Each tile 800 defines a boundary 801 with the adjacent tile. At least one waveguide 802 of a tile is in optical communication with at least one waveguide 802 of an adjacent tile across boundary 801. Each tile further includes programmable optical switches 810 which can be controlled to route signal to any desired destination within the PIC (e.g., to a particular optical RX 181). Being implemented through reticle stitching, PIC 102 may be substantially larger than the size of a conventional reticle (e.g., 32 mm×26 mm). For example, PIC 102 may have an area larger than 1000 mm², larger than 1500 mm², larger than 2000 mm², larger than 3000 mm² or larger than 5000 mm².

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some case and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within ±20% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The terms “couple,” “coupled,” and “coupling,” when used in connection with optical components, are to be interpreted broadly to include both direct and indirect coupling. Two optical components are considered directly coupled if there are no intervening components between them. In contrast, two optical components are considered indirectly coupled if there is at least one intervening component between them, provided that the intervening component does not alter the general nature of the interaction between the optical components.

What is claimed is:

1. A photonic-electronic package, comprising:
a photonic integrated circuit (PIC) comprising a first plurality of through silicon vias (TSV) and a second plurality of TSVs;
an electronic integrated circuit (EIC) mounted on the PIC, wherein the EIC comprises:
an input-output (I/O) interface coupled to the first plurality of TSVs of the PIC;
a plurality of serializer-deserializer (SerDes) coupled to the second plurality of TSVs of the PIC; and
a data path coupling the I/O interface to at least one of the plurality of SerDes.

2. The photonic-electronic package of claim 1, wherein the I/O interface is implemented in accordance with a Universal Chiplet Interconnect Express (UCIe) standard.

3. The photonic-electronic package of claim 1, wherein the PIC further comprises a plurality of optical transmitters, wherein the second plurality of TSVs couple the plurality of optical transmitters to the plurality of SerDes.

4. The photonic-electronic package of claim 3, wherein the PIC further comprises a waveguide and a fiber attach, wherein the waveguide couples the fiber attach to the plurality of optical transmitters.

5. The photonic-electronic package of claim 1, further comprising a substrate and an electronic chip, wherein the PIC is mounted on the substrate and the electronic chip is mounted on the substrate.

6. The photonic-electronic package of claim 5, wherein the substrate comprises a silicon bridge coupling the PIC to the electronic chip.

7. The photonic-electronic package of claim 6, wherein the silicon bridge is implemented in accordance with an Embedded Multi-die Interconnect Bridge (EMIB) standard.

8. The photonic-electronic package of claim 5, wherein the I/O interface of the EIC is implemented in accordance with a UCle standard, and the electronic chip has an I/O interface that is implemented in accordance with the UCIe standard.

9. The photonic-electronic package of claim 5, wherein the electronic chip comprises a plurality of nodes arranged in accordance with an N×M grid, wherein N>1 and M>1.

10. The photonic-electronic package of claim 9, wherein a first node of the plurality of nodes is a 180°-rotated version of a second node of the plurality of nodes.

11. The photonic-electronic package of claim 1, wherein the first plurality of TSVs have a first pitch and the second plurality of TSVs have a second pitch, wherein the second pitch is different from the first pitch.

12. The photonic-electronic package of claim 11, wherein the second pitch is between 30 μm and 120 μm and the first pitch is between 30 μm and 90 μm.

13. The photonic-electronic package of claim 1, wherein the EIC is hybrid-bonded to the PIC.

14. The photonic-electronic package of claim 1, wherein the EIC is configured to perform link training, telemetry, statistics and/or performance optimization.

15. The photonic-electronic package of claim 1, further comprising a plurality of trans-impedance amplifiers (TIA) coupled to the plurality of SerDes, wherein the plurality of TIAs are formed in the PIC or in the EIC.

16. A method of operating a photonic-electronic package comprising a substrate, a photonic integrated circuit (PIC) mounted on the substrate, an electronic chip and an electronic integrated circuit (EIC) mounted on the PIC, the method comprising:
controlling an optical receiver formed on the PIC to generate electric signals by receiving optical signals though a fiber attach formed on the PIC;
controlling a serializer/deserializer (SerDes) formed on the EIC to generate a serialized electrical signal upon receiving the electric signals from the optical receiver through a first set of through silicon vias (TSVs);
controlling a first I/O interface, formed on the EIC, to transmit a message derived from the serialized electrical signal to a second I/O interface, formed on the electronic chip, through a second set of TSVs; and
controlling the second I/O interface to provide the message to the electronic chip.

17. The method of claim 16, wherein the first and second I/O interfaces are implemented in accordance with a Universal Chiplet Interconnect Express (UCIe) standard.

18. The method of claim 16, further comprising controlling one or more optical switches to route the optical signals from the fiber attach to the optical receiver.

19. The method of claim 16, wherein transmission of the message from the first I/O interface to the second I/O interface passes through a silicon bridge implemented in accordance with an Embedded Multi-die Interconnect Bridge (EMIB) standard.

20. The method of claim 16, further comprising controlling the EIC to perform link training, telemetry, statistics and/or performance optimization on a data path coupling the SerDes to the first I/O interface.
